(19) United States
(12) Patent Application Publication
(10) Pub. No.: US 2026/0107423 A1
(43) Pub. Date: Apr. 16, 2026

(54) IMMERSED HEAT DISSIPATION STRUCTURE

(71) Applicant: MetaPWR Electronics Co., Ltd., Shanghai (CN)

(72) Inventors: Shouyu HONG, Shanghai (CN); Jianhong ZENG, Shanghai (CN); Hongxiu LIU, Shanghai (CN); Yahong Xiong, Shanghai (CN)

(73) Assignee: MetaPWR Electronics Co., Ltd., Shanghai (CN)

(21) Appl. No.: 19/356,195

(22) Filed: Oct. 13, 2025

(30) Foreign Application Priority Data
Oct. 14, 2024 (CN) 202411432795.3

(51) Int. Cl. H05K 7/20

(52) U.S. Cl. CPC H05K 7/20927

(57) ABSTRACT

The application discloses an immersed heat dissipation structure, a protective cover is mounted on the outer side of the power supply module, and an opening structure is provided on a side surface of the protective cover, so as to prevent metal particles in the cooling liquid from entering the power supply module, thereby improving the safety and reliability of the module. And, the coolant can flow inside the module through the opening structure of the protective cover, or the internal or surface parts of the gasification take-away module are transferred to the inside of the module by means of the substrate.

### CROSS-REFERENCE TO RELATED APPLICATION

This application claims the priority benefit of Chinese application serial no. 202411432795.3, filed on October 14, 2024. The entirety of the above-mentioned patent application is hereby incorporated by reference herein and made a part of this specification.

### BACKGROUND

### TECHNICAL FIELD

The present application relates to an immersed heat dissipation structure.

### DESCRIPTION OF RELATED ART

With the increasing requirements of various types of artificial intelligence, data processing, etc., the computing power of various types of board cards is continuously increased, and the power consumption of a computing chip is also increased year by year. Since the size limitation of these computing power units is extremely high, higher and higher requirements are provided for the occupied area, heat dissipation, etc. of the energy processing unit.

In order to reduce the footprint of the energy processing unit, the 3D stacked power mode composition is a trend; in order to improve the heat dissipation performance of the power supply module, immersion cooling can be used; however, some conductive particles, such as solder balls from the surface of the PCBA assembly, are easily entrained in the cooling liquid. These conductive particles may flow in the cooling liquid, which may create a bridge between adjacent electrodes, resulting in some functional failures and even catastrophic failures such as burning loss or failure of the power module and the computing chip.

In order to solve the problem, there is usually a need to coat conformal coating on the surface of a printed circuit board assembly (PCBA) to achieve surface insulation. However, when 3D stacked power module is employed, elements between the stacks are difficult to be applied to the insulating material. Therefore, how to effectively protect these positions is an urgent problem to be solved.

### SUMMARY

In view of the above, one of the objectives of the application is to provide an immersed heat dissipation structure, comprising:

a power supply module, a mainboard and a protective cover; the power supply module comprises a substrate, and the substrate comprises an upper surface and a lower surface opposite to each other, and a side surface; the side surface of the substrate is provided between the upper surface and the lower surface of the substrate; at least one element is provided on the upper surface and the lower surface of the substrate;

the mainboard comprises an upper surface and a lower surface opposite to each other; the upper surface of the mainboard is disposed adjacent to the lower surface of the substrate;

the protective cover includes a lower edge surface and a side surface; the side surface of the protective cover extends from the upper surface of the mainboard to the substrate of the power supply module; a projection contour of the protective cover on a horizontal plane completely envelopes a projection contour of the power supply module on a same horizontal plane; the side surface of the protective cover has an opening structure, and a length of cross-section of the opening structure at least one dimension is less than 0.15 mm.

Preferably, the protective cover comprises at least two side surfaces provided with the opening structure, and an area ratio of openings on one side surface is greater than 10%.

Preferably, the opening structure is directly formed by means of an injection mold, or is implemented by means of a machining method such as mechanical and laser.

Preferably, the protective cover further comprises an upper edge surface, the lower edge surface and the upper surface of the mainboard are fixed by a bonding material, and the upper edge surface and the substrate are fixed by means of a bonding material.

Preferably, the protective cover comprises an upper edge surface, the upper edge surface is higher than the upper surface of the substrate, and the upper surface of the mainboard and an inner side surface of the protective cover are fixed by a bonding material.

Preferably, a gap between the protective cover and the mainboard is filled with a bonding material, and a gap between the protective cover and the substrate is filled with a bonding material; the bonding material is insoluble in an immersion cooling liquid; and the bonding material comprises organic silica gel, acrylic resin, polyimide, and polyurethane.

Preferably, the protective cover comprises a frame, and the frame is made of an insulating material; or an inner portion of the frame is a metal material, and a surface of the frame is an insulating material.

Preferably, the protective cover further comprises a skin structure, and the skin structure and the frame are assembled by means of any one of bonding, skin tension or interference fit; a thickness of the skin structure is less than 500 µm; and the opening structure of the skin structure is formed by laser cutting small holes or photosensitive material light painting processing.

Preferably, the protective cover further comprises a mesh structure, the mesh structure comprises at least one woven screen mesh, and a screen hole diameter of the woven screen mesh is less than 0.15 mm in at least one dimension; and a material of the woven screen mesh is glass fiber or organic fiber.

Preferably, a height of the protective cover is higher than a height of the power supply module, and the protective cover further comprises an upper cover plate; and the protective cover and the power supply module are assembled on the mainboard, and the protective cover completely envelopes the power supply module.

Preferably, the power supply module further comprises an adapter plate and a connector, the adapter plate comprises an upper surface and a lower surface opposite to each other, the connector is disposed between the adapter plate and the mainboard, and a lower surface of the adapter plate is adjacent to and fixed to the upper surface of the mainboard.

Preferably, the protective cover is a layer of mesh structure, and an inner side surface of the mesh structure is fixedly connected to the side surface of the substrate and a side surface of the adapter plate.

Preferably, after the protective cover is fixedly connected to the side surface of the substrate and a side surface of the adapter plate, the power supply module is then assembled with the mainboard.

Preferably, the immersed heat dissipation structure, further comprising a metal plate, wherein the protective cover further comprises an upper edge surface, and a height of the protective cover is greater than a height of the power supply module; the metal plate is disposed on the upper edge surface; the metal plate comprises an upper surface and a lower surface opposite to each other; the lower surface of the metal plate is thermally connected to a heating element in the power supply module by means of a thermally conductive interface material, and the thermally conductive interface material is a curable thermally conductive material.

Preferably, the lower surface of the metal plate further comprises a step, and the step is thermally connected to the heating element in the power supply module by means of the thermally conductive interface material; and the thermally conductive interface material is a curable thermally conductive material.

Preferably, the metal plate further comprises an exhaust hole, and a pore size of the exhaust hole is less than 0.15 mm; and an arrangement position of the exhaust hole avoids a thermal connection region.

### Compared with the prior art, the application has the following beneficial effects:

The present application provides an immersed heat dissipation structure. A protective cover is mounted on an outer side of a power supply module, and an opening structure is provided on a side surface of the protective cover, so as to prevent metal particles in the cooling liquid from entering the power supply module and improve the safety and reliability of the module.

The cooling liquid can flow inside the module through the opening structure of the protective cover to take away the heat inside the module or the surface part passing through the substrate to the inside, thereby improving the heat dissipation capability of the module.

On the other hand, the present application provides various embodiments of a protective cover, which are applicable to different application scenarios.

### BRIEF DESCRIPTION OF THE DRAWINGS

FIG. 1A to FIG. 1D are schematic diagrams of an immersed heat dissipation structure;

FIG. 2A to FIG. 2C are schematic diagrams of stacked power supply modules;

FIG. 3A to FIG. 3D are fixed schematic diagrams of a protective cover and a mainboard and a power supply module;

FIG. 4A and FIG. 4B are schematic structural diagrams of another protective cover;

FIG. 5A and FIG. 5B are schematic structural diagrams of another protective cover;

FIG. 6A and FIG. 6B are schematic diagrams of another immersed heat dissipation structure;

FIG. 7 is a schematic diagram of another immersed heat dissipation structure.

### DESCRIPTION OF THE EMBODIMENTS

One of the cores of the present application is to provide an immersed heat dissipation structure. A protective cover is mounted on the outer side of the power supply module, and an opening structure is provided on the side surface of the protective cover to prevent metal particles in the cooling liquid from entering the power supply module, thereby improving the safety and reliability of the module. At the same time, the cooling liquid can flow inside the module through the opening structure of the protective cover to take away the heat inside the module or the surface part passing through the substrate to the inside, thereby improving the heat dissipation capability of the module.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

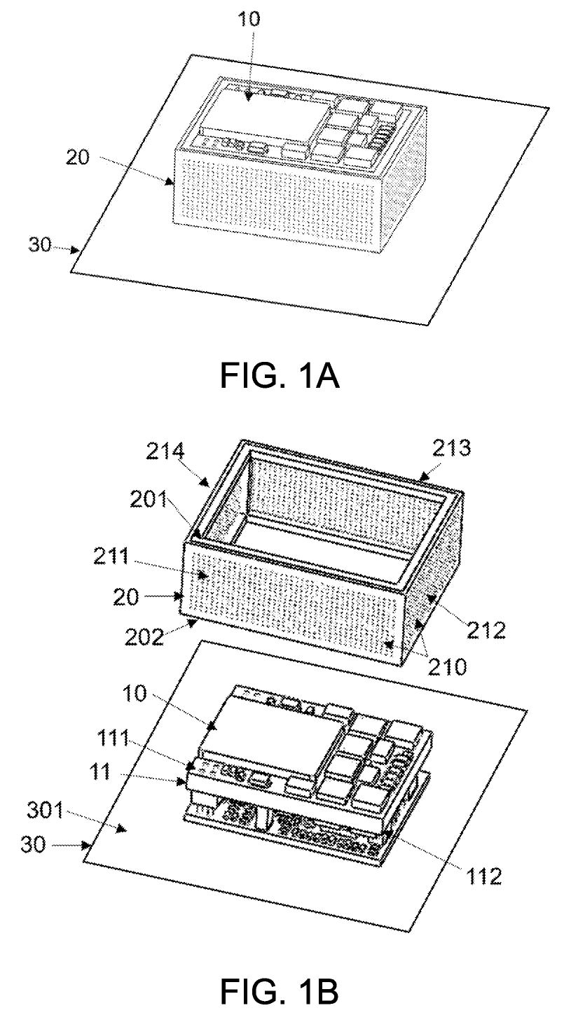

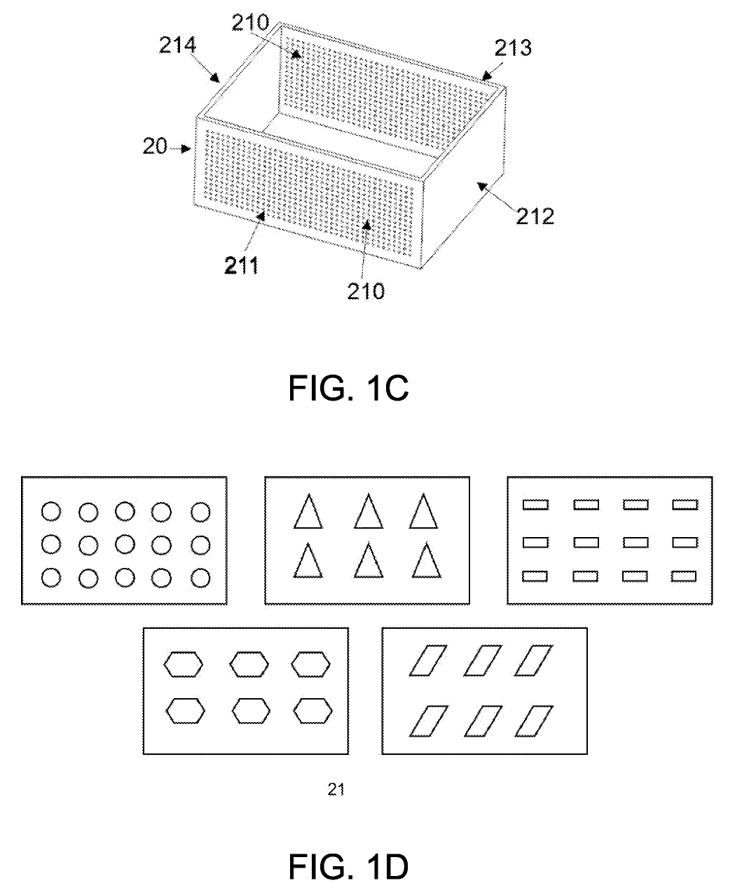

The immersed heat dissipation structure provided by the present application is shown in FIG. 1A and FIG. 1B; FIG. 1A is a schematic structural diagram, and FIG. 1B is an exploded schematic diagram. With reference to FIG. 1A and 1B, the power module 10 is provided on the upper surface 301 of the mainboard 30, and the protective cover 20 is provided at the periphery of the power module 10. The power supply module 10 comprises a substrate 11, wherein the substrate 11 comprises an upper surface 111 and a lower surface 112 opposite to each other, and the plurality of elements are respectively arranged on the upper surface 111 and the lower surface 112; and the lower surface 112 of the substrate 11 is arranged adjacent to the upper surface 301 of the mainboard 30. The power module further comprises four sides disposed between the upper surface 111 and the lower surface 112. The protective cover 20 comprises a first side surface 211 and a third sides surface 213 opposite to each other, a second side surface 212 and a fourth side surface 214 opposite to each other, an upper edge face 201 and a lower edge face 202. Multiple openings are provided on the first side surface 211 and the fourth side surface 214. When the protective cover 20 is assembled with the mainboard 30 and the power module 10, the lower edge surface 202 of the protective cover 20 is attached to the upper surface 301 of the mainboard 30, and the protective cover 20 extends in the height direction from the upper surface 301 of the mainboard to the substrate 11 of the power module; the projection contour of the protective cover 20 on a horizontal plane completely envelope the projection contour of the power supply module 10 in the same horizontal direction. The protective cover 20 can be made of a material having a uniform thickness. The protective cover 20 can also have a non-equal-thickness feature, for example, a position where the opening structure needs to be provided is thinner to facilitate the fabrication of the opening structure, and a position of the structural support is relatively thick to provide sufficient strength. In another embodiment, as shown in FIG. 1C, the opening structure 210 may be disposed only on the first side surface 211 and the third side surface 213, or on the second side surface 212 and the fourth side surface 214. In the two-phase liquid cooling occasion, an opening structure 210 is provided on at least two side surfaces, so as to ensure that the two-phase liquid has a good vapor vent channel and a liquid supplementary channel.

As shown in FIG. 1D, the opening structure 210 of the protective cover 20 may be in the shape of a circular hole, a triangular hole, a square hole, a rhombic hole, or a hexagonal hole; and the opening has a cross-sectional dimension of less than 0.15 mm in at least one direction, that is, there is at least one straight line passing through the center of the cross-sectional of the opening, and the length of the straight line in the opening is less than 0.15 mm. When the power module with the protective cover operates in an immersion liquid cooling, the risk of a short circuit caused by the metal particles in the cooling liquid entering the module is greatly reduced, and the safety and reliability of the power supply module are improved; in addition, because of the existence of the opening structure, the cooling liquid can flow inside the module through the opening structure of the protective cover to take away the heat inside the module or the heat passing through the substrate to the inside, thereby improving the heat dissipation capability of the module; on the other hand, the protective cover is relatively completely sealed, and the aperture structure provides a pressure relief channel, thereby avoiding the risk of the protective cover falling off in the application.

On the other hand, the area ratio of the opening in one side surface of the present application is greater than 10%, thereby ensuring sufficient liquid/gasification transmission capability. The opening structure 210 can be directly formed by means of an injection mold, or can be implemented by means of a machining method such as mechanical and laser.

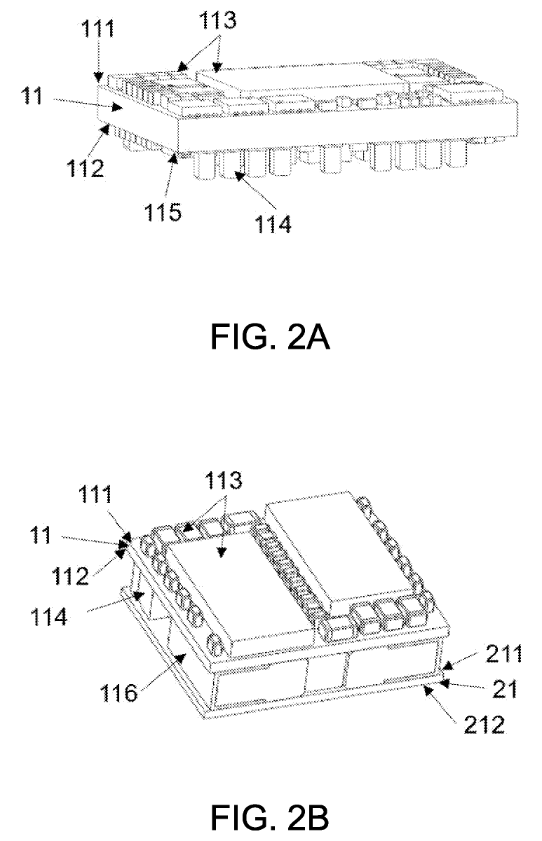

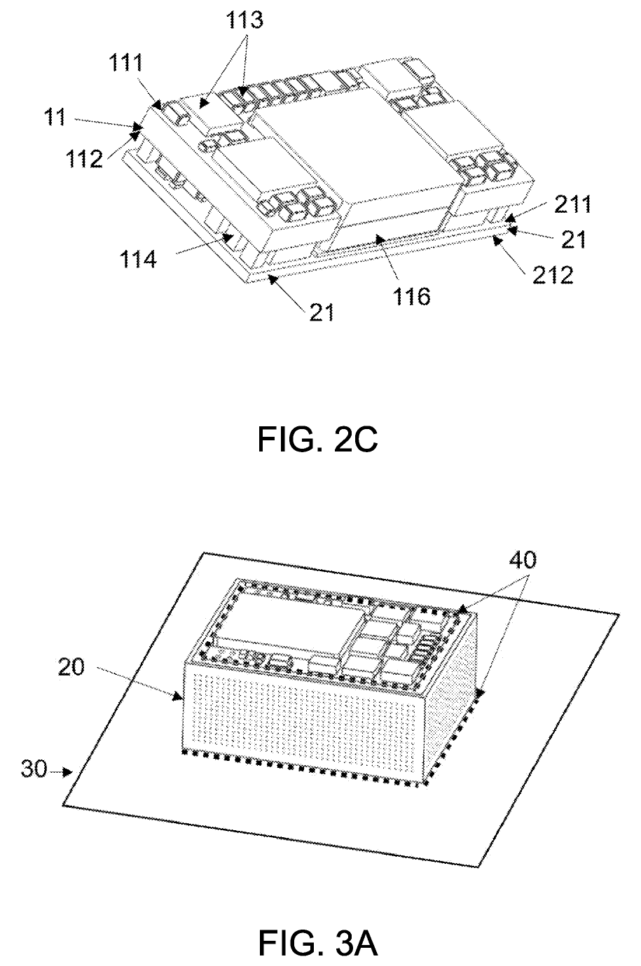

The immersed heat dissipation structure is applicable to the stacked power supply module shown in FIG. 2A to FIG. 2C. As shown in FIG. 2A, the power supply module comprises a substrate 11, and the substrate 11 comprises an upper surface 111 and a lower surface 112 opposite to each other. The plurality of elements 113 are arranged on the upper surface 111, and the element 115 and the connecting member 114 are arranged on the lower surface 112. The power supply module is fixedly electrically connected to the mainboard by means of the connector 114. As shown in FIG. 2B, the power supply module comprises a substrate 11 and an adapter plate 12. The substrate 11 comprises an upper surface 111 and a lower surface 112 opposite to each other, and the adapter plate 12 comprises an upper surface 121 and a lower surface 122 opposite to each other, and the upper surface 121 of the adapter plate is arranged adjacent to the lower surface 112 of the substrate. The plurality of elements 113 are arranged on the upper surface 111, and the connector 114 and the inductor assembly 116 are arranged between the substrate 11 and the adapter plate 21. The power supply module is fixed and electrically connected to the mainboard 30 by means of the adapter plate, and the lower surface 212 of the adapter plate is connected to the mainboard 30. A power module as shown in FIG. 2C, comprising a substrate 11 and an adapter plate 12, wherein the substrate 11 comprises an upper surface 111 and a lower surface 112 opposite to each other; the adapter plate 12 comprises an upper surface 121 and a lower surface 122 opposite to each other, and the upper surface 121 of the adapter plate is arranged adjacent to the lower surface 112 of the substrate. The plurality of elements 113 are arranged on the upper surface 111; the magnetic core assembly 116 is assembled to the substrate 11; the connector 114 is arranged between the substrate 11 and the adapter plate 21; and the power supply module is fixed and electrically connected to the mainboard 30 by means of the adapter plate, and the lower surface 212 of the adapter plate is connected to the mainboard 30.

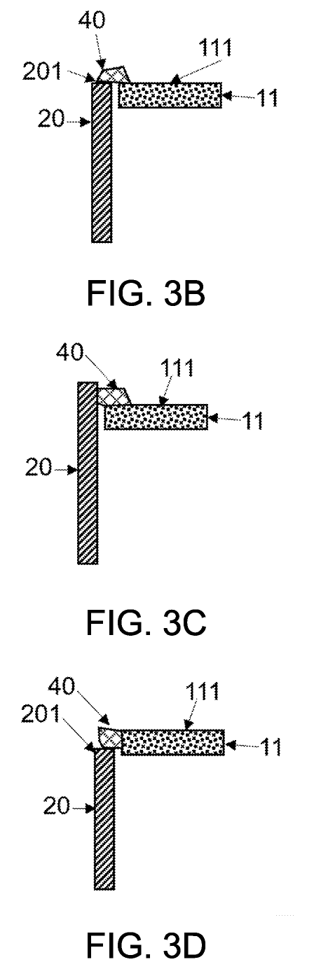

The present application further discloses a fixing method of the protective cover 20 and the power supply module 10 and the mainboard 30, as shown in FIG. 3A to FIG. 3D. As shown in FIG. 3A, the bonding material 40 is disposed between the lower edge surface 202 of the protective cover and the upper surface 301 of the motherboard, securing the protective cover to the main board, and filling the gap between the protective cover and the main board. The bonding material 40 may also be disposed between an upper edge surface 201 of the protective cover and an upper surface 111 of the substrate for securing the protective cover and the power module. In detail, as shown in FIG. 3B, the upper edge surface 201 of the protective cover and the upper surface 111 of the substrate are approximately on the same plane, and the bonding material 40 is provided on the edge surface 201 and the upper surface 111, thereby fixing the protective cover 20 and the substrate 11, and filling the gap between the protective cover 20 and the substrate 11; as shown in FIG. 3C, the upper edge surface 201 of the protective cover is higher than the upper surface 111 of the substrate, and the bonding material 40 is arranged on the upper surface 111 and the inner side surface of the protective cover, thereby fixing the protective cover 20 and the substrate 11, and filling the gap between the protective cover 20 and the substrate 11. Optionally, the upper edge surface 201 of the protective cover is higher than the cavity formed by the upper surface 111 of the substrate, and the insulating glue is injected into the cavity to protect the elements on the upper surface 111 of the substrate. As shown in FIG. 3D, the upper surface 111 of the substrate is higher than the upper edge face 201 of the protective cover, the bonding material 40 is provided between the upper edge surface 201 and the side surface of the substrate to fix the protective cover 20 and the substrate 11 and fill the gap between the protective cover 20 and the substrate 11. The side surface of the substrate 11 and the inner side wall of the protective cover 20 are attached to each other, and a gap between the two is preferably less than 0.15 mm. The bonding material 40 is made of a material which is insoluble in the immersion cooling liquid, such as epoxy glue, organic silica gel, acrylic resin, polyimide, polyurethane, etc. In addition, the bottom of the protective cover 20 and the mainboard 30 can be mechanically locked (the bottom of the protective cover can be provided with a horizontally extending structure for locking, not shown), the same fixing effect can also be achieved, and the gap between the protective cover and the mainboard is less than 0.15 mm.

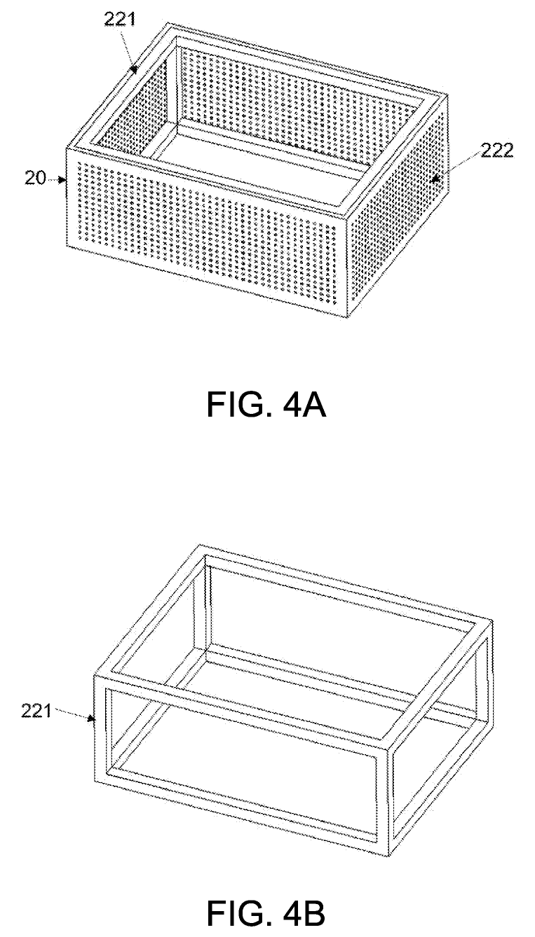

The structure of the protective cover disclosed in the present application is shown in FIG. 4A and 4B. The protective cover 20 comprises a frame 221 and a skin 222, and the skin 222 is assembled together with the frame 221 by means of bonding, skin tension or interference fit. The frame 221 can be made of an insulating material, or the inner portion of the frame can be an metal material, but the surface is a composite structure of an insulating material. The metal member provides strength support for the frame, and the surface insulating material provides an insulating effect for the frame. The skin 222 can be made of extremely thin skin, such as less than 500 µm in thickness, and a thickness of less than 200 µm is optimal; the opening structure on the skin 222 can be formed by laser cutting small holes or photosensitive material light-painting; the skin structure can further increase the gaseous/liquid flow of the cooling liquid, and the processing difficulty of the opening structure is reduced due to the thinner thickness of the skin.

In addition, a mesh structure can also be used to replace the skin, and is assembled with the frame to implement the protective cover. The mesh structure may be a woven mesh, and the woven material may be glass fiber, organic fiber, etc. The pore size of the mesh structure is less than 0.15 mm in at least one dimension; in order to ensure the stability of the mesh size of the mesh structure, the organic material may be locally fixed, for example, after the woven mesh is impregnated with the photosensitive colloidal material, the photosensitive colloidal material is photochemically defined. Furthermore, the mesh structure may be one layer or multiple layers, so as to prevent the single-layer screen from breaking under the impact of the coolant flow and the exhaust gas inside the module. The multi-layer structure may also increase the reliability of the mesh structure. Furthermore, the opening structure of each layer of mesh structure in the multi-layer structure may be inconsistent, thereby better blocking the foreign matter from entering the power supply module. Furthermore, the skin can be one layer or multiple layers, and can be disposed immediately adjacent to each other, and can also be arranged at intervals (the corresponding frame structure can be adaptively modified so as to support a multilayer skin), so as to achieve a better conductive particle rejection effect.

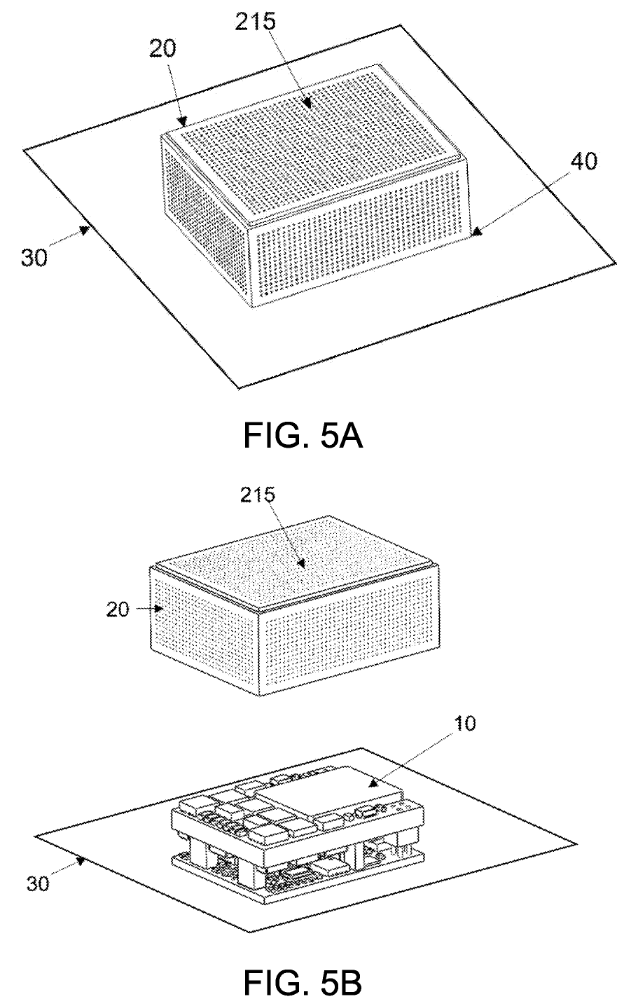

The protective cover 20 may also include an upper cover plate 215, which may refer to FIG. 5A and FIG. 5B at the same time. The upper cover plate 215 is not specifically referred to as an independent component, may be a part of the integrated protective cover, or may be a part of an integral skin. When the protective cover 20 is assembled on the mainboard 30, the power supply module can be fully envelope. The protective cover only needs to be assembled with the mainboard, it’s a simple process, and reduces the stress generated by the power module tolerance and thermal expansion and contraction on the bonding position when the protective cover is connected up and down at the same time, thereby increasing connection reliability.

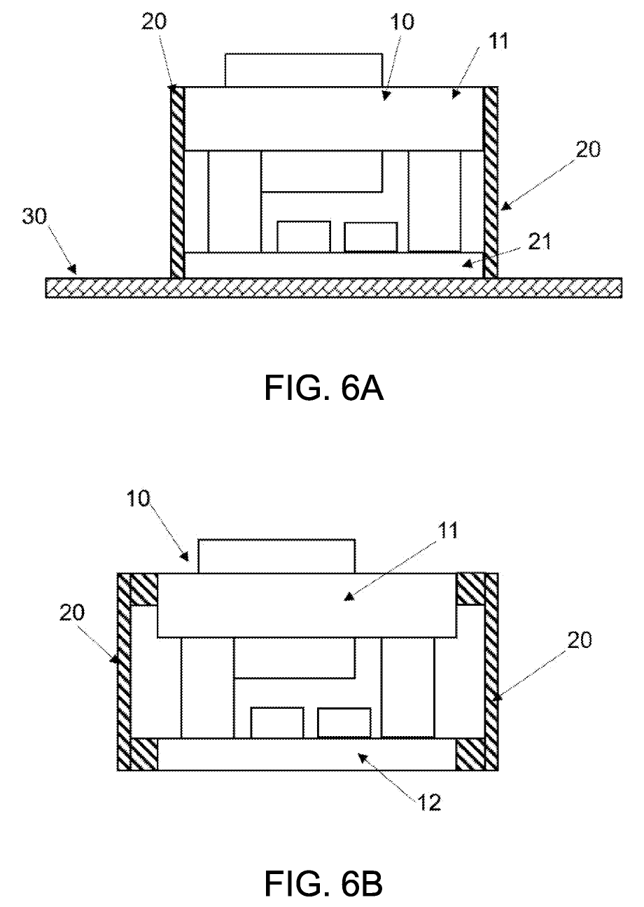

In another embodiment, as shown in FIG. 6A, the protective cover 20 can also be directly fixed on the side surfaces of the substrate 11 and the adapter plate 21 by using only one layer of mesh structure, that is, the substrate 11 and the adapter plate 21 are used as a frame to fix the mesh structure, the same protective effect can also be achieved, and the structure does not require an additional assembly step, and the process is simple; there is no need to expand the frame outwards, the space is saved, and the power density is improved. In another embodiment, as shown in FIG. 6B, the protective cover 20 may be first assembled with the power supply module, i.e. bonded and fixed to the side surfaces of the substrate 11 and the adapter plate 21, and then assembled and fixed with the mainboard together with the module. The structure reduces the assembly process of the client, and the customer is more convenient to use.

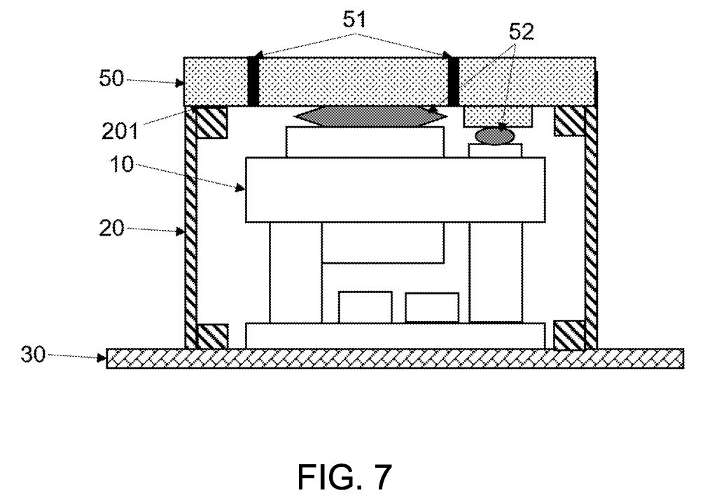

The present application further discloses an immersed heat dissipation structure, as shown in FIG. 7. The heat dissipation structure further comprises a metal plate 50, and the metal plate 50 is arranged above the protective cover 20. The power supply module 10 is first assembled on the upper surface 301 of the mainboard, and then the protective cover 20 is fixedly connected to the mainboard 30, and the height of the protective cover 20 is higher than the height of the power supply module 10. The metal plate 50 is provided on the upper edge surface 201 of the protective cover, and the metal plate 50 can be thermally connected to the heating device by means of the heat conduction interface material 52. The lower surface of the metal plate can also be provided with a step, and the heat conduction interface material 52 is thermally connected to the heating devices at different heights, thereby reducing the equivalent thermal resistance on the heat conduction path and achieving a better heat dissipation effect. The metal plate 50 further comprises an exhaust hole 51, the exhaust hole 51 may be one or more, and the pore size of the exhaust hole is less than 0.15 mm. The arrangement position of the exhaust hole is as long as the thermal contact region between the metal plate and the heating device is avoided, and a thermally conductive interface material 52, wherein the curable thermally conductive material is optimal.

The power supply module according to the embodiment can be an independent module or a part of the electronic device, and can meet the technical features and advantages disclosed by the application.

The " equal " or " same " or " equal to " disclosed by the application needs to consider the parameter distribution of engineering, and the error distribution is within +/-30%; and the included angle between the two line segments or the two straight lines is less than or equal to 45 degrees; the included angle between the two line segments or the two straight lines is within the range of [ 60, 120 ]; and the definition of the phase error phase also needs to consider the parameter distribution of the engineering, and the error distribution of the phase error degree is within +/-30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. An immersed heat dissipation structure, comprising:
a power supply module, a mainboard and a protective cover; the power supply module comprises a substrate, and the substrate comprises an upper surface and a lower surface opposite to each other, and a side surface; the side surface of the substrate is provided between the upper surface and the lower surface of the substrate; at least one element is provided on the upper surface and the lower surface of the substrate;
the mainboard comprises an upper surface and a lower surface opposite to each other; the upper surface of the mainboard is disposed adjacent to the lower surface of the substrate;
the protective cover includes a lower edge surface and a side surface; the side surface of the protective cover extends from the upper surface of the mainboard to the substrate of the power supply module; a projection contour of the protective cover on a horizontal plane completely envelopes a projection contour of the power supply module on a same horizontal plane; the side surface of the protective cover has an opening structure, and a length of cross-section of the opening structure at least one dimension is less than 0.15 mm.

2. The immersed heat dissipation structure of claim 1, wherein the protective cover comprises at least two side surfaces provided with the opening structure, and an area ratio of openings on one side surface is greater than 10%.

3. The immersed heat dissipation structure of claim 2, wherein the opening structure is directly formed by means of an injection mold, or is implemented by means of a machining method such as mechanical and laser.

4. The immersed heat dissipation structure of claim 1, wherein the protective cover further comprises an upper edge surface, the lower edge surface and the upper surface of the mainboard are fixed by a bonding material, and the upper edge surface and the substrate are fixed by means of a bonding material.

5. The immersed heat dissipation structure of claim 1, wherein the protective cover comprises an upper edge surface, the upper edge surface is higher than the upper surface of the substrate, and the upper surface of the mainboard and an inner side surface of the protective cover are fixed by a bonding material.

6. The immersed heat dissipation structure of claim 1, wherein a gap between the protective cover and the mainboard is filled with a bonding material, and a gap between the protective cover and the substrate is filled with a bonding material; the bonding material is insoluble in an immersion cooling liquid; and the bonding material comprises organic silica gel, acrylic resin, polyimide, and polyurethane.

7. The immersed heat dissipation structure of claim 1, wherein the protective cover comprises a frame, and the frame is made of an insulating material; or an inner portion of the frame is a metal material, and a surface of the frame is an insulating material.

8. The immersed heat dissipation structure of claim 7, wherein the protective cover further comprises a skin structure, and the skin structure and the frame are assembled by means of any one of bonding, skin tension or interference fit; a thickness of the skin structure is less than 500 µm; and the opening structure of the skin structure is formed by laser cutting small holes or photosensitive material light painting processing.

9. The immersed heat dissipation structure of claim 7, wherein the protective cover further comprises a mesh structure, the mesh structure comprises at least one woven screen mesh, and a screen hole diameter of the woven screen mesh is less than 0.15 mm in at least one dimension; and a material of the woven screen mesh is glass fiber or organic fiber.

10. The immersed heat dissipation structure of claim 1, wherein a height of the protective cover is higher than a height of the power supply module, and the protective cover further comprises an upper cover plate; and the protective cover and the power supply module are assembled on the mainboard, and the protective cover completely envelopes the power supply module.

11. The immersed heat dissipation structure of claim 1, wherein the power supply module further comprises an adapter plate and a connector, the adapter plate comprises an upper surface and a lower surface opposite to each other, the connector is disposed between the adapter plate and the mainboard, and a lower surface of the adapter plate is adjacent to and fixed to the upper surface of the mainboard.

12. The immersed heat dissipation structure of claim 11, wherein the protective cover is a layer of mesh structure, and an inner side surface of the mesh structure is fixedly connected to the side surface of the substrate and a side surface of the adapter plate.

13. The immersed heat dissipation structure of claim 11, wherein after the protective cover is fixedly connected to the side surface of the substrate and a side surface of the adapter plate, the power supply module is then assembled with the mainboard.

14. The immersed heat dissipation structure of claim 1, further comprising a metal plate, wherein the protective cover further comprises an upper edge surface, and a height of the protective cover is greater than a height of the power supply module; the metal plate is disposed on the upper edge surface; the metal plate comprises an upper surface and a lower surface opposite to each other; the lower surface of the metal plate is thermally connected to a heating element in the power supply module by means of a thermally conductive interface material, and the thermally conductive interface material is a curable thermally conductive material.

15. The immersed heat dissipation structure of claim 14, wherein the lower surface of the metal plate further comprises a step, and the step is thermally connected to the heating element in the power supply module by means of the thermally conductive interface material; and the thermally conductive interface material is a curable thermally conductive material.

16. The immersed heat dissipation structure of claim 14, wherein the metal plate further comprises an exhaust hole, and a pore size of the exhaust hole is less than 0.15 mm; and an arrangement position of the exhaust hole avoids a thermal connection region.
